(19) United States
(12) Patent Application Publication
(10) Pub. No.: US 2025/0385226 A1
(43) Pub. Date: Dec. 18, 2025

(54) ELECTRONIC DEVICES AND A METHODS OF MANUFACTURING ELECTRONIC DEVICES

(71) Applicant: Amkor Technology Singapore Holding Pte. Ltd., Singapore (SG)

(72) Inventors: Wang Gu Lee, Seoul (KR); Kyun Ahn, Gyeonggi-do (KR); In Su Mok, Incheon (KR)

(21) Appl. No.: 18/943,203

(22) Filed: Nov. 11, 2024

Related U.S. Application Data
(60) Provisional application No. 63/659,510, filed on Jun. 13, 2024.

(51) Int. Cl. H01L 25/10; H01L 23/00; H01L 23/498; H01L 25/00

(52) U.S. Cl. CPC H01L 25/105; H01L 24/24; H01L 24/82; H01L 25/50; H01L 23/49811; H01L 2224/24137; H01L 2224/24146; H01L 2224/244; H01L 2224/24996; H01L 2224/82138; H01L 2225/1041

(57) ABSTRACT

A method of manufacturing an electronic device may include providing alignment conductive pads and internal interconnects along an upper side of a first carrier and coupling alignment interconnects of a connect component to the alignment conductive pads. The method also includes encapsulating the connect component and the internal interconnects in a lower encapsulant, and covering an upper side of the lower encapsulant with an upper substrate. The method also includes coupling, via the upper substrate, first interconnects of a first electronic component and a second electronic component to the connect component interconnects and second interconnects of the first electronic component and the second electronic component to the internal interconnects. The method further includes removing the first carrier from a lower side of the lower encapsulant, and covering the lower side of the lower encapsulant with a lower substrate. Other examples and related electronic devices are also disclosed herein.

### CROSS-REFERENCE TO RELATED APPLICATIONS/INCORPORATION BY REFERENCE

This application makes reference to, claims priority to, and claims benefit from U.S. Provisional Application Ser. No. 63/659,510, filed on Jun. 13, 2023, and titled “Electronic Devices and a Methods of Manufacturing Electronic Devices,” the entire contents of which are hereby incorporated herein by reference.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2I show cross-sectional views of an example method for manufacturing an example electronic device.

FIG. 3A shows a cross-sectional view of an example connect component on alignment conductive pads of a carrier.

FIG. 3B shows a cross-sectional view of the example connect component of FIG. 3A after being subjected to a heat-treatment.

FIG. 4A shows a cross-section view of an example connect component having a signal distribution structure.

FIG. 4B shows a cross-section view of an example connect component having through interconnects.

FIG. 4C shows a cross-section view of an example connect component having through interconnects and a backside signal distribution structure.

FIG. 5 shows a cross-sectional view of an example electronic device.

FIGS. 6A to 6C show cross-sectional views of an example method for manufacturing an example electronic device.

FIG. 7 shows a cross-sectional view of an example electronic device.

### DESCRIPTION

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” “third,” etc. may be used herein to describe various elements, and the elements described using these terms should not be limited by the “first,” “second,” “third,” etc. The terms “first,” “second,” “third,” etc. are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A may be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to an electrical coupling or a mechanical coupling.

An example method of manufacturing an electronic device may include providing alignment conductive pads and internal interconnects along an upper side of a first carrier and coupling alignment interconnects of a connect component to the alignment conductive pads. The method also includes encapsulating the connect component and the internal interconnects in a lower encapsulant, and covering an upper side of the lower encapsulant with an upper substrate. The method also includes coupling, via the upper substrate, first interconnects of a first electronic component and a second electronic component to the connect component interconnects and second interconnects of the first electronic component and the second electronic component to the internal interconnects. The method further includes removing the first carrier from a lower side of the lower encapsulant, and covering the lower side of the lower encapsulant with a lower substrate.

An example electronic device may include a lower substrate, an upper substrate, internal interconnects, a connect component, a lower encapsulant, a first electronic component, a second electronic component, and lower substrate interconnects. The internal interconnects may couple an upper side of the lower substrate to a lower side of the upper substrate. The connect component may include component interconnects along an upper side of the connect component and alignment interconnects along a lower side of the connect component. The component interconnects may be coupled to the lower side of the upper substrate and the alignment interconnects may be coupled to the upper side of the upper substrate. The lower encapsulant may encapsulate the internal interconnects and the connect component. The first electronic component may be coupled to the internal interconnects and the connect component via the upper side of the upper substrate. The second electronic component may be coupled to the internal interconnects and the connect component via the upper side of the upper substrate. The lower substrate interconnects may be provided along the lower side of the lower substrate.

Other examples are included in the present disclosure. Such examples may be found in the figures, in the claims, or in the description of the present disclosure.

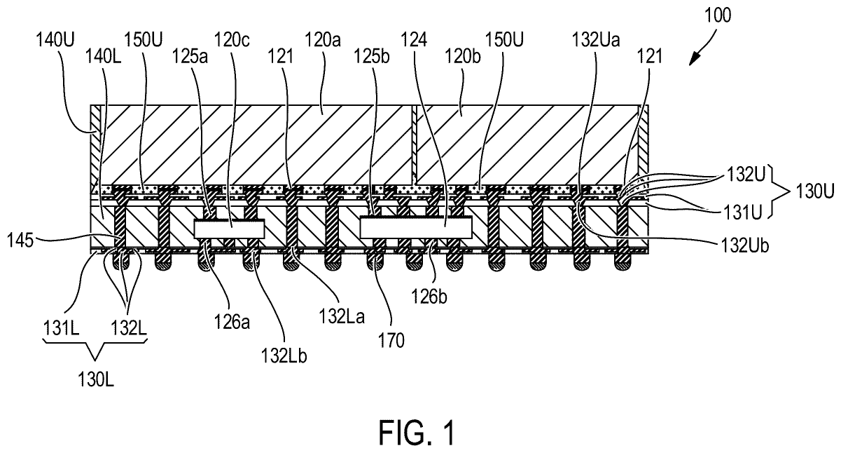

FIG. 1 shows a cross-sectional view of an example the electronic device 100. In the example shown in FIG. 1, the electronic device 100 may comprise one or more electronic components, such as first electronic component 120a, second electronic component 120b, and third electronic component 120c, one or more connect component(s) 124, an upper substrate 130U, a lower substrate 130L, an upper encapsulant 140U, a lower encapsulant 140L, internal interconnects 145, and lower substrate interconnects 170. In some examples, the electronic device 100 may comprise an upper underfill 150U.

The first electronic component 120a and the second electronic component 120b may each comprise component interconnects 121. The third electronic component 120c and the connect component 124 may respectively comprise component interconnects 125a, 125b. Further, the third electronic component 120c and the connect component 124 may respectively comprise alignment interconnects 126a, 126b.

The upper substrate 130U may comprise an upper substrate dielectric structure 131U and an upper substrate conductive structure 132U. The upper substrate conductive structure 132U may comprise upper substrate upper terminals 132Ua and upper substrate lower terminals 132Ub. The lower substrate 130L may comprise a lower substrate dielectric structure 131L and a lower substrate conductive structure 132L. The lower substrate conductive structure 132L may comprise lower substrate upper terminals 132La and lower substrate lower terminals 132Lb.

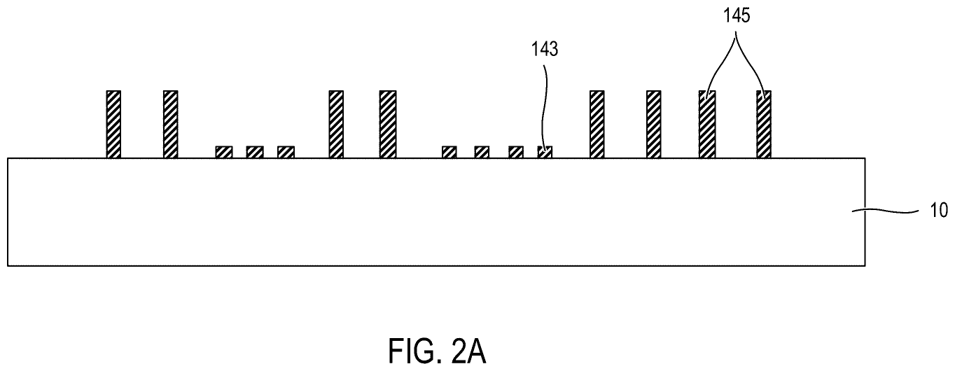

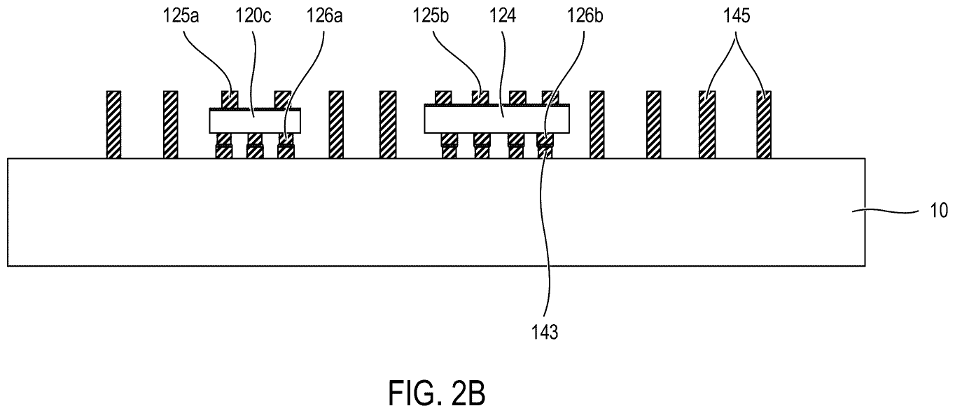

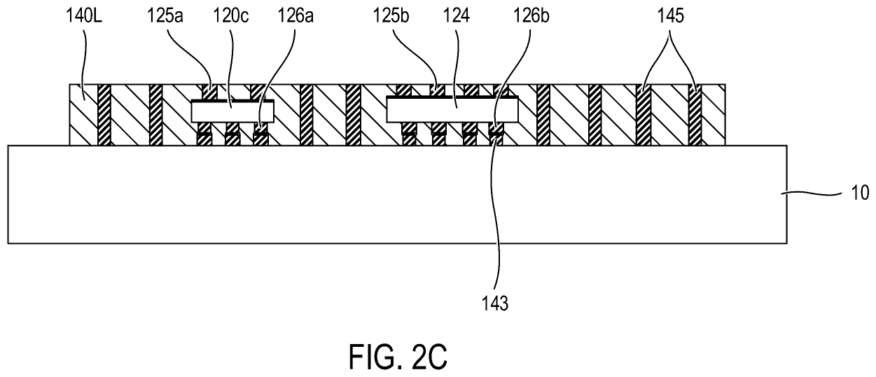

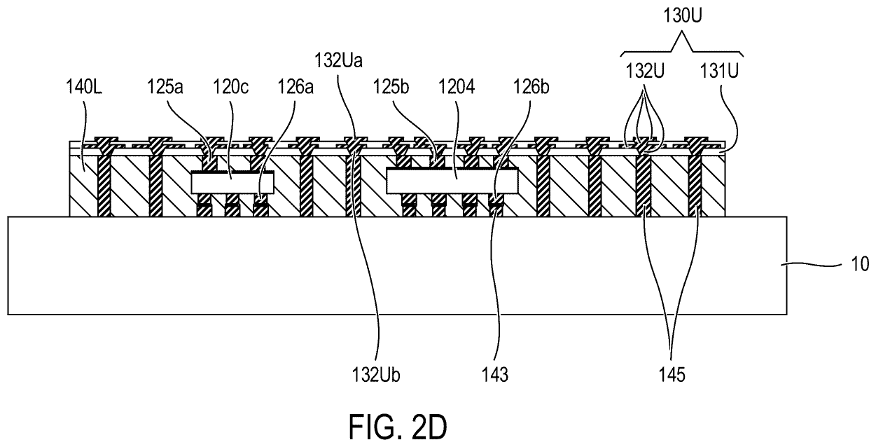

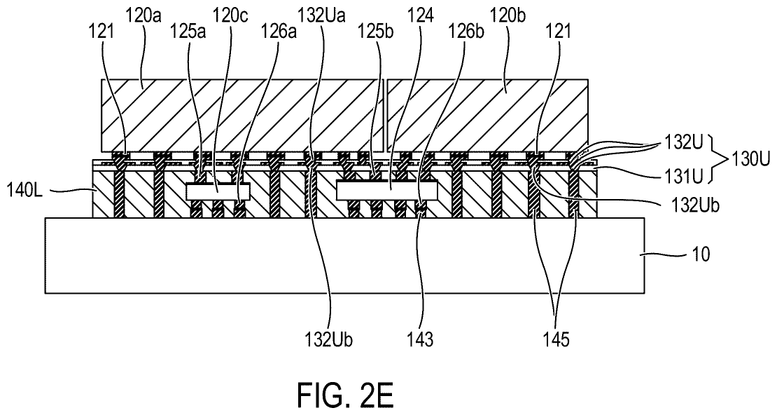

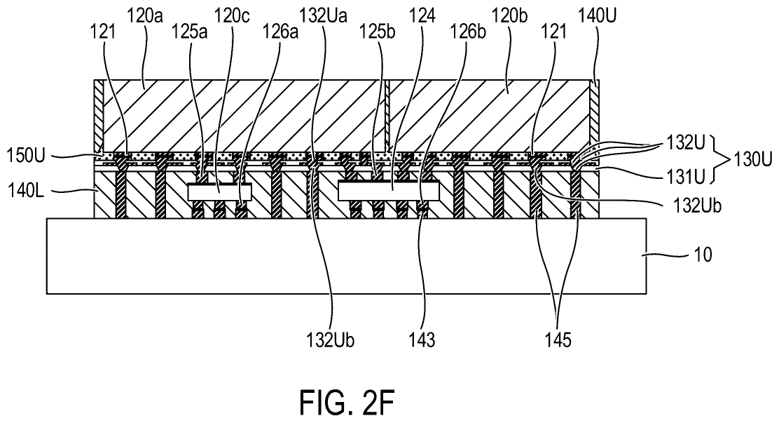

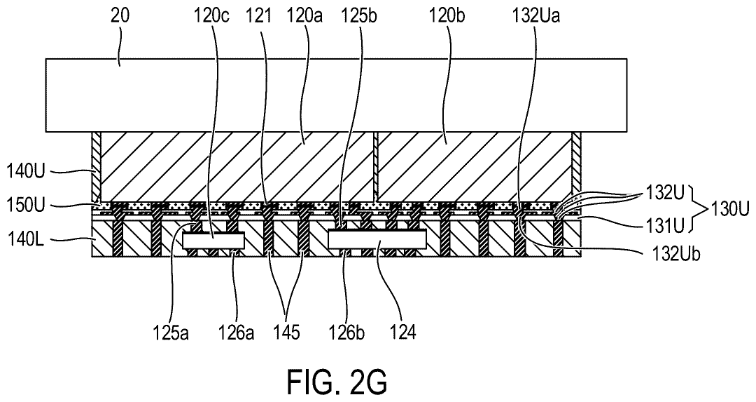

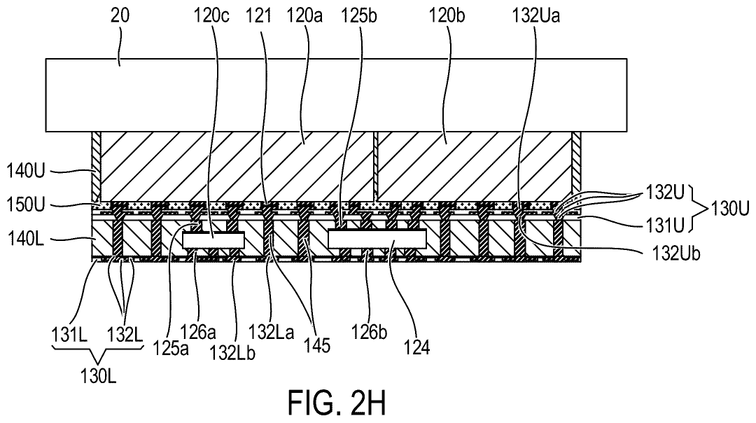

FIGS. 2A to 2I show cross-sectional views of an example method for manufacturing the electronic device 100. FIG. 2A shows a cross-sectional view of the electronic device 100 at an early stage of manufacture. In the example shown in FIG. 2A, internal interconnects 145 and alignment conductive pads 143 may be provided on an upper side of first carrier 10.

In accordance with various examples, the alignment conductive pads 143 and the internal interconnects 145 may be made of a conductive material such as, for example, copper, gold, silver, palladium, or nickel. The alignment conductive pads 143 and/or the internal interconnects 145 may be provided by electrolytic plating, electroless plating, sputtering, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD), or ball drop. In some examples, a seed layer may be formed on the upper side of first carrier 10, and then a mask pattern may be provided on the upper side of the seed layer. The alignment conductive pads 143 and the internal interconnects 145 may be formed by plating over exposed portions of the seed layer. In some examples, the alignment conductive pads 143 and the internal interconnects 145 may be provided by different mask patterns. After the alignment conductive pads 143 and internal interconnects 145 are provided, the mask pattern(s) may be removed. In some examples, the alignment conductive pads 143 may be provided before providing the internal interconnects 145.

The alignment conductive pads 143 and the internal interconnects 145 may be provided in rows and/or columns on the first carrier 10. The alignment conductive pads 143 may be provided in an area where the third electronic component 120c and connect component 124 (FIG. 2B) are to be seated.

In some examples, the height (i.e., thickness) of the internal interconnects 145 may be greater than the height of the alignment conductive pads 143. The thickness of each alignment conductive pad 143 may range from approximately 0.5 micrometers (μm) to approximately 100 μm. In some examples, the height of each internal interconnect 145 may range from approximately 20 μm to approximately 800 μm. The internal interconnects 145 may comprise or be referred to as vertical conductive structures such as pillars, posts, through mold vias (TMVs), copper core solder balls (CCBs), or solder balls, or copper cube columns (CCCs). In accordance with various examples, CCCs may include a plurality of vertical conductive structures (e.g., columns, pillars, posts, etc.) disposed in an insulating body, such as mold material (e.g., an epoxy mold compound, resin, organic polymer with inorganic filler, etc.).

The first carrier 10 may comprise a substantially planar plate. In some examples, the first carrier 10 may comprise or be referred to as a plate, board, wafer, panel, or strip. For example, the first carrier 10 may be provided as a wafer. In some examples, the thickness of the first carrier 10 may range from approximately 50 μm to approximately 800 μm, and the width of the first carrier 10 may range from approximately 100 millimeters to approximately 300 mm. In some examples, the width of first carrier 10 may be greater than 300 (e.g., first carrier may have a width of 600 mm). The first carrier 10 may serve to integrally handle a number of components in the process of providing the alignment conductive pads 143, the internal interconnects 145, the electronic components 120a, 120b, 120c, the connect component 124, the substrates 130U, 130L, and the encapsulants 140U, 140L.

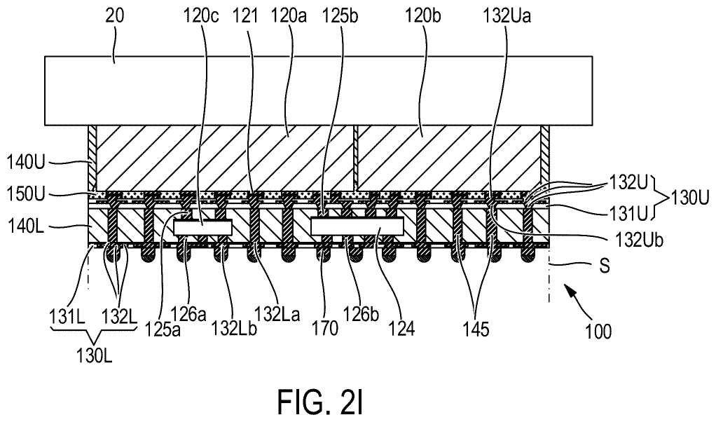

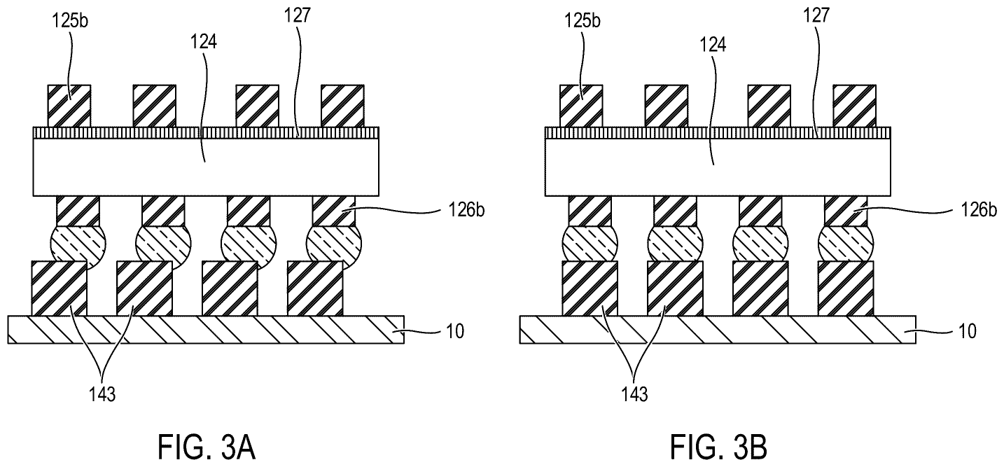

FIG. 2B shows a cross-sectional view of the electronic device 100 at a later stage of manufacture. In the example shown in FIG. 2B, the connect components 124 may be provided over the alignment conductive pads 143 on the upper side of first carrier 10. In particular, the third electronic component 120c and the connect component 124 may be provided over the alignment conductive pads 143 on the upper side of the first carrier 10. FIG. 3A shows the connect component 124 after being provided on the alignment conductive pads 143 on the upper side of the first carrier 10. FIG. 3B shows the connect component 124 after being provided on the alignment conductive pads 143 on the upper side of the first carrier 10 and then subsequently subjected to a heat-treatment (e.g., a reflow operation).

The third electronic component 120c may comprise a component upper side and a component lower side. In some examples, the component upper side may comprise or be referred to as an active side, and the component lower side may comprise or be referred to as an inactive side. The third electronic component 120c may comprise component interconnects 125a provided on the component upper side. The component interconnects 125a may be provided to be spaced apart from each other in a row and/or column direction. The component interconnects 125a may comprise or be referred to as pads, bumps, pillars, conductive posts, or solder balls. The component interconnects 125a may comprise conductive material such as aluminum, copper, an aluminum alloy, a copper alloy, solder, etc. The component interconnects 125a may be input/output terminals of third electronic component 120c. The component interconnects 125a may be electrically connected to the third electronic component 120c. In some examples, the third electronic component 120c may comprise or be referred to as a passive device (e.g., a capacitor, resistor, inductor, etc.) or an Intelligent Power Device (IPD). The thickness (i.e., height) of each component interconnect 125a may range from approximately 0.5 μm to approximately 300 μm.

The third electronic component 120c may comprise alignment interconnects 126a provided on the component lower side. The alignment interconnects 126a may be similar to the component interconnects 125a. The alignment interconnects 126a may be disposed on the component lower side with an area and pitch corresponding to those of the alignment conductive pads 143.

In some examples, the alignment interconnects 126a may comprise or be referred to as pads, bumps, pillars, conductive posts, or solder balls. In some examples, the alignment interconnects 126a may include conductive posts having solder caps provided on the ends of the conductive posts.

The connect component 124 may comprise a connect component upper side and a connect component lower side. The connect component 124 may comprise component interconnects 125b on the connect component upper side and alignment interconnects 126b on the connect component lower side. In some examples, the connect component 124 may be referred to as a connection die or bridge die. The connect component 124 may transmit signals between the first electronic component 120a and the second electronic component 120b (FIG. 1). In some examples, the connect component 124 may transmit signals between the upper substrate 130U and the lower substrate 130L, with momentary reference to FIG. 1. The component interconnects 125b of the connect component 124 may be provided to be spaced apart from each other in a row and/or column direction. The component interconnects 125b may comprise or be referred to as pads, bumps, pillars, conductive posts, or solder balls. The component interconnects 125b may comprise conductive material such as aluminum, copper, an aluminum alloy, a copper alloy, solder, etc. The thickness (i.e., height) of each component interconnect 125b may range from approximately 0.5 μm to approximately 300 μm.

The alignment interconnects 126b of the connect component 124 may be similar to the alignment interconnects 126a. For example, the alignment interconnects 126b may be disposed on the connect component lower side with an area and pitch corresponding to those of the alignment conductive pads 143. The alignment interconnects 126b may comprise or be referred to as pads, bumps, pillars, conductive posts, or solder balls. In some examples, the alignment interconnects 126b may include conductive posts having solder caps provided on the ends of the conductive posts.

In some examples, the third electronic component 120c and the connect component 124 may be picked up by pick-and-place equipment and placed on an upper side of the alignment conductive pads 143 on the first carrier 10. Subsequently, the alignment interconnects 126a, 126b of the third electronic component 120c and the connect component 124 may be aligned and fixed on the alignment conductive pads 143 through heat treatment. Even if the alignment interconnects 126b are misaligned on the upper side of the alignment conductive pads 143 as shown in FIG. 3A, the connect component 124 may be aligned and affixed to the alignment conductive pads 143 through heat treatment as shown in FIG. 3B. In this manner, the third electronic component 120c and the connect component 124 may be aligned and fixed in position on the first carrier 10 by the alignment conductive pads 143 and the alignment interconnects 126a, 126b. In some examples, the overall thickness of connect component 124 may range from approximately 10 μm to approximately 800 μm, and the area of connect component 124 may range from approximately 0.5 mm×0.5 mm to approximately 100 mm×100 mm. In some examples, the thickness of third electronic component 120c may be similar to the thickness of connect component 124.

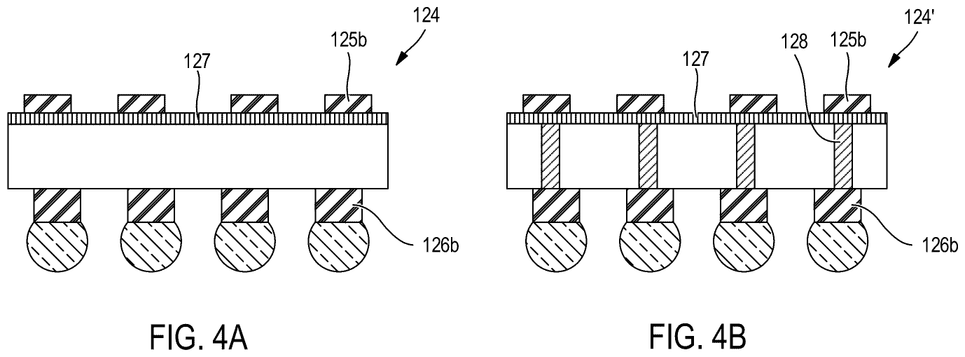

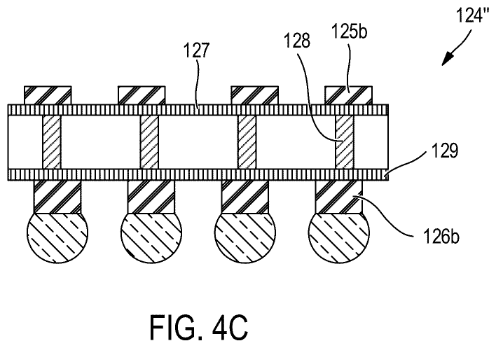

FIGS. 4A, 4B, and 4C provide enlarged views of the connect component 124, a connect component 124′, and a connect component 124″, respectively. The connect component 124 shown in FIG. 4A may comprise a signal distribution structure 127 having a fine conductive pattern provided on the upper side of connect component 124. It is contemplated and understood that signal distribution structure 127 can include multiple conductive layers and/or fine conductive patterns built-up over one another with interleaving dielectric layers. In some examples, the dielectric layers of signal distribution structure 127 can comprise an inorganic dielectric material, such as, for example, silicon nitride (Si₃N₄), silicon oxide (SiO₂), and/or silicon oxynitride (SiON). In some examples, the dielectric layers of signal distribution structure 127 can comprise an organic dielectric material, such as, for example, polyimide (PI), benzocyclobutene (BCB), polybenzoxazole (PBO), or Ajinomoto Buildup Film (ABF). The fine conductive pattern(s) of the signal distribution structure 127 may electrically couple first electronic component 120a to second electronic component 120b. In some examples, the connect component 124 may be devoid of active components (e.g., transistors) and may comprise only the signal distribution structure 127 formed over the base material of the connect component 124. In some examples, connect component 124 can comprise a semiconductor material such as silicon. In some examples, the connect component 124 can comprise a mold material, ceramic, or glass. In the example of FIG. 4A, component interconnects 125b may be coupled to signal distribution structure 127 and alignment interconnects 126b may be electrically isolated from signal distribution structure 127.

As another example, the connect component 124′ shown in FIG. 4B may comprise through interconnects 128. Through interconnects 128 may penetrate connect component 124′ and couple the alignment interconnects 126b along the connect component lower side to one or more of the component interconnects 125b located along the connect component upper side. For example, through interconnect 128 may couple the alignment interconnects 126b to the signal distribution structure 127. The central portion (e.g., the base material) of the connect component 124′ may comprise a semiconductor material, mold material, ceramic, or glass through which the through interconnects 128 pass.

As another example, the connect component 124″ shown in FIG. 4C may comprise backside signal distribution structure 129. Backside signal distribution structure 129 may be similar to signal distribution structure 127. For example, backside signal distribution structure 129 may comprise one or more conductive layers interleaved with one or more dielectric layers. Through interconnects 128 may electrically couple backside signal distribution structure 129 to signal distribution structure 127. The alignment interconnects 126b may be coupled to the lower side of backside signal distribution structure 129. In this regard, backside signal distribution structure 129 may electrically couple one or more of the alignment interconnects 126b to through interconnects 128. In some examples, the dielectric layers of backside signal distribution structure 129 may be similar to the dielectric layers of signal distribution structure 127 (e.g., both backside signal distribution structure 129 and signal distribution structure 127 may include inorganic or organic dielectric layers). In some examples, the dielectric layers of backside signal distribution structure 129 may comprise organic dielectric material and the dielectric layers of signal distribution structure 127 may comprise inorganic dielectric material.

Returning to FIG. 2C a cross-sectional view of the electronic device 100 at a later stage of manufacture is shown. In the example shown in FIG. 2C, the lower encapsulant 140L may be provided to cover the first carrier 10, the third electronic component 120c and the connect component 124, the alignment conductive pads 143, and the internal interconnects 145. The lower encapsulant 140L may be in contact with the upper side of the first carrier 10, the sidewalls of the third electronic component 120c and the connect component 124, the upper side and sidewalls of the alignment conductive pads 143, and the sidewalls of the internal interconnects 145. The upper side of each component interconnect 125a, 125b and the upper side of each internal interconnect 145 may be exposed at the upper side of lower encapsulant 140L.

In some examples, the lower encapsulant 140L may comprise or be referred to as a body or a molding. For example, the lower encapsulant 140L may comprise an epoxy mold compound, resin, organic polymer with inorganic filler, a curing agent, a catalyst, a coupling agent, a colorant, or a flame retardant, and may be formed by compression molding, transfer molding, liquid body molding, vacuum lamination, paste printing, or film-assisted molding. In some examples, after the lower encapsulant 140L is provided to cover the upper side and sidewall of third electronic component 120c and the connect component 124, the sidewall of each alignment conductive pads 143, and the upper side and sidewall of each internal interconnect 145, the upper portion of the lower encapsulant 140L may be removed to expose the upper side of each component interconnect 125a, 125b and the upper side of each internal interconnect 145.

For example, the upper portion of the lower encapsulant 140L may be removed by a general grinding and/or chemical etching of the upper side of the lower encapsulant 140L. The thickness of the lower encapsulant 140L may range from approximately 20 μm to approximately 800 μm. The lower encapsulant 140L may protect the third electronic component 120c and the connect component 124, the alignment conductive pads 143, and the internal interconnects 145 from external elements.

FIG. 2D shows a cross-sectional view of the electronic device 100 at a later stage of manufacture. In the example shown in FIG. 2D, the upper substrate 130U may be provided over and/or covering the lower encapsulant 140L, the third electronic component 120c and the connect component 124, and the internal interconnects 145.

The upper substrate 130U may comprise an upper substrate dielectric structure 131U and an upper substrate conductive structure 132U. The upper substrate conductive structure 132U may comprise upper substrate upper terminals 132Ua and upper substrate lower terminals 132Ub.

The upper substrate dielectric structure 131U may comprise one or more dielectric layers and the upper substrate conductive structure 132U may comprise one or more conductive layers. In particular, the upper substrate dielectric structure 131U may comprise multiple dielectric layers that are alternately stacked or interleaved with one or more conductive layers of the upper substrate conductive structure 132U. Portions of the upper substrate conductive structure 132U located at the upper side of the upper substrate dielectric structure 131U may be referred to as upper substrate upper terminals 132Ua. Portions of the upper substrate conductive structure 132U in contact with the component interconnects 125a, 125b and/or with the internal interconnects 145 may be referred to as upper substrate lower terminals 132Ub.

The upper substrate dielectric structure 131U may comprise an electrically insulating material such as polyimide (PI), benzocyclobutene (BCB), polybenzoxazole (PBO), resin, or Ajinomoto buildup film (ABF) and may be formed by spin coating, spray coating, dip coating, rod coating, PVD, CVD, or any other suitable formation method. Upper substrate dielectric structure 131U may be provided over and/or covering the lower encapsulant upper side, the upper sides of the third electronic component 120c and the connect component 124, and the upper side of each internal interconnects 145. In some examples, after the lower (or first) layer of the upper substrate dielectric structure 131U is provided, openings exposing the upper side of component interconnects 125a, 125b and the upper side of internal interconnects 145 may be provided. For example, after forming a mask pattern on the upper side of the lower layer of upper substrate dielectric structure 131U, openings may be formed by removing exposed portions of the dielectric layer through etching. Portions of upper substrate conductive structure 132U may then be provided in the openings, such that the portions of upper substrate conductive structure 132U are coupled to and/or contacting component interconnects 125a, 125b and internal interconnects 145.

The upper substrate conductive structure 132U may be interleaved with the upper substrate dielectric structure 131U. The upper substrate conductive structure 132U may be in contact with and electrically connected to the internal interconnects 145 and to the component interconnects 125a, 125b of the third electronic component 120c and the connect component 124, respectively. The upper substrate conductive structure 132U can comprise one or more conductive layers defining signal distribution elements (e.g., traces, vias, pads, conductive paths, or UBM). The upper substrate conductive structure 132U can provide signal and power distribution in the vertical and horizontal directions through upper substrate 130U. The upper substrate conductive structure 132U may comprise copper, gold, silver, aluminum, nickel, palladium, titanium, tungsten, or any other suitable conductive material. The upper substrate conductive structure 132U may be provided by electrolytic plating, electroless plating, sputtering, PVD, CVD, MOCVD, ALD, LPCVD, PECVD, or any other suitably metal deposition process. In some examples, the upper substrate conductive structure 132U may be provided by plating. For example, after a metal seed layer is provided to cover the component interconnects 125a, 125b, the internal interconnects 145, and the dielectric layer of upper substrate dielectric structure 131U, a mask pattern may be provided to cover the upper side of a seed layer. The conductive layer of the upper substrate conductive structure 132U may then be provided through plating using exposed portions of the seed layer as a seed. For example, a photoresist may be used as the mask pattern. After the conductive layer is formed, the mask pattern may be removed.

The completed upper substrate 130U is shown with a two-layer upper substrate dielectric structure 131U and a two-layer upper substrate conductive structure 132U. However, the number of layers constituting the upper substrate dielectric structure 131U and the number of layers constituting the upper substrate conductive structure 132U may be fewer than or more than two. One or more conductive layers or elements of the upper substrate conductive structure 132U may be interleaved with one or more dielectric layers of the upper substrate dielectric structure 131U. The upper substrate upper terminals 132Ua and the upper substrate lower terminals 132Ub may be provided above and below the upper substrate 130U and may be spaced apart from each other in the row and/or column directions.

In some examples, the upper substrate 130U may comprise a redistribution layer (“RDL”) substrate. RDL substrates may comprise one or more conductive layers and one or more dielectric layers. RDL substrates may be formed (a) layer by layer over an electronic component to which the RDL substrate is to be coupled, or (b) layer by layer over a carrier that may be entirely removed or at least partially removed after the electronic component and the RDL substrate are coupled together. RDL substrates may be manufactured layer by layer as a wafer-level substrate on a round wafer in a wafer-level process, and/or as a panel-level substrate on a rectangular or square panel carrier in a panel-level process. RDL substrates may be formed in an additive buildup process and may include one or more dielectric layers alternatingly stacked with one or more conductive layers that define respective conductive redistribution patterns or traces configured to collectively (a) fan-out electrical traces outside the footprint of the electronic component, and/or (b) fan-in electrical traces within the footprint of the electronic component.

The conductive patterns may be formed using a plating process such as, for example, an electroplating process or an electroless plating process. The conductive patterns may comprise a conductive material such as, for example, copper or other plateable metal. The locations of the conductive patterns may be made using a photo-patterning process such as, for example, a photolithography process and a photoresist material to form a photolithographic mask. The dielectric layers of the RDL substrate may be patterned with a photo-patterning process, and may include a photolithographic mask through which light is exposed to photo-pattern desired features such as vias in the dielectric layers.

The dielectric layers may be made from photo-definable organic dielectric materials such as, for example, polyimide (PI), benzocyclobutene (BCB), or polybenzoxazole (PBO). Such dielectric materials may be spun-on or otherwise coated in liquid form, rather than attached as a pre-formed film. To permit proper formation of desired photo-defined features, such photo-definable dielectric materials may omit structural reinforcers or may be filler-free, without strands, weaves, or other particles that may interfere with light from the photo-patterning process. In some examples, such filler-free characteristics of filler-free dielectric materials may permit a reduction of the thickness of the resulting dielectric layer. Although the photo-definable dielectric materials described above may be organic materials, in some examples the dielectric materials of the RDL substrate may comprise one or more inorganic dielectric layers. Some examples of inorganic dielectric layer(s) may comprise silicon nitride (Si3N4), silicon oxide (SiO2), and/or silicon oxynitride (SiON). The inorganic dielectric layer(s) may be formed by growing the inorganic dielectric layers using an oxidation or nitridization process instead of using photo-defined organic dielectric materials. Such inorganic dielectric layers may be filler-fee, without strands, weaves, or other dissimilar inorganic particles. In some examples, RDL substrates may omit a permanent core structure or carrier such as, for example, a dielectric material comprising bismaleimide triazine (BT) or FR4 and these types of RDL substrates may comprise or be referred to as a coreless substrate. Other substrates of this disclosure such as the device substrate 110 and/or the lower substrate 130L and/or the signal distribution structure 127 and/or the backside signal distribution structure 129 may comprise RDL substrates.

In some examples, the upper substrate 130U may comprise a pre-formed or laminate substrate. The pre-formed substrate may be manufactured prior to attachment to an electronic component and may comprise dielectric layers between respective conductive layers. The conductive layers may comprise copper and may be formed using an electroplating process. The dielectric layers may be relatively thicker non-photo-definable layers and may be attached as a pre-formed film rather than as a liquid and may include a resin with fillers such as strands, weaves, and/or other inorganic particles for rigidity and/or structural support. Since the dielectric layers are non-photo-definable, features such as vias or openings may be formed by using a drill or laser. In some examples, the dielectric layers may comprise a prepreg material or Ajinomoto Buildup Film (ABF). The pre-formed substrate may include a permanent core structure or carrier such as, for example, a dielectric material comprising bismaleimide triazine (BT) or FR4, and dielectric and conductive layers may be formed on the permanent core structure. In other examples, the pre-formed substrate may be a coreless substrate and omits the permanent core structure, and the dielectric and conductive layers may be formed on a sacrificial carrier that is removed after formation of the dielectric and conductive layers and before attachment to the electronic component. The pre-formed substrate may be referred to as a printed circuit board (PCB) or a laminate substrate. Such pre-formed substrates may be formed through a semi-additive or modified-semi-additive process. Other substrates of this disclosure such as the device substrate 110 and the lower substrate 130L may comprise a pre-formed substrate.

FIG. 2E shows a cross-sectional view of the electronic device 100 at a later stage of manufacture. In the example shown in FIG. 2E, the first electronic component 120a and the second electronic component 120b may be provided on the upper side of upper substrate 130U. Each of the first electronic component 120a and the second electronic component 120b may comprise component interconnects 121.

Pick-and-place equipment may pick up the first and second electronic components 120a, 120b and place the first and second electronic components 120a, 120b on the upper side of upper substrate 130U. The component interconnects 121 of each of first and second electronic components 120a, 120b may be located on the upper side of respective upper substrate upper terminals 132Ua. Subsequently, the component interconnects 121 of the first and second electronic components 120a, 120b may be in contact with and be bonded with upper substrate upper terminals 132Ua through a reflow, thermal compression, or hybrid bonding process. The first and second electronic components 120a, 120b may be electrically connected to each other through upper substrate 130U and the connect component 124. In particular, first ones of the component interconnects 121 may couple their respective electronic component 120 to the connect component 124 via the upper substrate 130U and second ones of the component interconnects 121 may couple their respective electronic component 120 to the internal interconnects 145 via the upper substrate 130U. In this manner, the component interconnects 121 may electrically couple the first and second electronic components 120a, 120b to the lower substrate 130L via the internal interconnects 145 and/or the connect component 124. Moreover, the component interconnects 121 may electrically couple first and second electronic components 120a, 120b to each other via the connect component 124. In accordance with various examples, of the component interconnects 121 that are coupled to the connect component 124 may have a narrow (or first) pitch and the component interconnects 121 that are coupled to the internal interconnects 145 may have a wide (or second pitch). For example, a first group of the component interconnects 121 of first electronic component 120a may have a first width and/or a first pitch and a second group of the component interconnects 121 of first electronic component 120a may have a second width and/or a second pitch that is greater than the first width and/or a first pitch, respectively. The component interconnects 121 of second electronic component 120b may be similar to the component interconnects 121 of first electronic component 120a.

In some examples, each of first electronic component 120a and second electronic component 120b may comprise or be referred to as a die, a chip, a package (e.g., an encapsulated device including one or more semiconductor die), an active device, or a passive device. Although the component interconnects 121 of electronic components 120 are shown as being coupled in a face-down or flip-chip configuration, there may be examples where the component interconnects 121 of electronic components 120 are coupled in a face-up or wire bond configuration. In some examples, the overall thickness of each electronic component 120 may range from approximately 30 μm to approximately 800 μm, and the area of each electronic component 120 may range from approximately 0.5 mm×0.5 mm to approximately 100 mm×100 mm.

FIG. 2F shows a cross-sectional view of the electronic device 100 at a later stage of manufacture. In the example shown in FIG. 2F, the upper underfill 150U may be provided between the upper substrate 130U and the first and second electronic components 120a, 120b. The upper encapsulant 140U may be provided to cover the first and second electronic components 120a, 120b. The upper underfill 150U may be in contact with the lower side of each of first and second electronic components 120a, 120b and may be in contact with the upper side of the upper substrate 130U. In some examples, the upper underfill 150U may be in contact with the component interconnects 121. The upper underfill 150U may comprise or be referred to as a dielectric layer or a non-conductive paste and may be free of inorganic fillers. In some examples, the upper underfill 150U may comprise or be referred to as a capillary underfill (CUF), a nonconductive paste (NCP), a nonconductive film (NCF), an anisotropic conductive film (ACF), or an anisotropic conductive paste (ACP). In some examples, the upper underfill 150U may be considered as part of the upper encapsulant 140U. In such examples, the upper encapsulant 140U may provide as molded underfill (MUF).

In some examples, the upper underfill 150U may be cured after being positioned between the first and second electronic components 120a, 120b and the upper substrate 130U. The upper underfill 150U may help prevent the first and second electronic components 120a, 120b from being separated from the upper substrate 130U due to physical and thermal impacts.

The upper encapsulant 140U may be provided to cover the first and second electronic components 120a, 120b, the upper substrate 130U, and the upper underfill 150U. The upper encapsulant 140U may contact sidewalls of the first and second electronic components 120a, 120b, an upper side of the upper substrate 130U, and a sidewall of the upper underfill 150U. In some examples, the upper encapsulant 140U may expose upper sides of the first and second electronic components 120a, 120b (e.g., the upper side of the upper encapsulant 140U may be coplanar with the upper sides of the first and second electronic components 120a, 120b).

In some examples, the upper encapsulant 140U may be in contact with sidewalls of the upper substrate 130U and sidewalls of the lower encapsulant 140L. The upper encapsulant 140U may have corresponding elements, features, materials, or manufacturing method similar to those of the lower encapsulant 140L.

FIG. 2G shows a cross-sectional view of the electronic device 100 at later stages of manufacture. In the example shown in FIG. 2G, a second carrier 20 is provided to over the upper sides of first and second electronic components 120a, 120b and the upper side of the upper encapsulant 140U. Further, the first carrier 10 has been removed from the lower sides of the lower encapsulant 140L, the alignment interconnect 126a, 126b, and the internal interconnects 145.

The second carrier 20 may comprise a temporary bond layer and may be in contact with the upper side of first and second electronic components 120a, 120b and the upper side of the upper encapsulant 140U. The second carrier 20 may have elements, features, materials, or manufacturing methods similar to or the same as those of the first carrier 10.

In response to the first carrier 10 being removed, the lower side of lower encapsulant 140L, the lower side of the internal interconnects 145, the lower side of third electronic component 120c and the lower side of connect component 124 may be exposed. For example, after the first carrier 10 is removed, the lower side of the lower encapsulant 140L, the lower side of the internal interconnects 145, and the lower sides of alignment interconnect 126a, 126b may be partially removed through grinding and/or etching. Further, the alignment conductive pads 143 may be removed through grinding and/or etching. The lower side of each internal interconnect 145 and the lower side of each alignment interconnect 126a, 126b may be exposed. However, in some examples, the alignment conductive pads 143 or portions therefore may be retained. In such embodiments, the lower side of each alignment conductive pad 143, instead of the lower side of each alignment interconnect 126a, 126b, may be exposed.

FIG. 2H shows a cross-sectional view of the electronic device 100 at later stages of manufacture. In the example shown in FIG. 2H, the lower substrate 130L may be provided to over and/or covering the lower side of the lower encapsulant 140L, the lower side of each internal interconnect 145, the lower side of third electronic component 120c and the lower side of connect component 124.

The lower substrate 130L may comprise the lower substrate dielectric structure 131L and the lower substrate conductive structure 132L. The lower substrate conductive structures 132L may comprise the lower substrate upper terminals 132La and the lower substrate lower terminals 132Lb.

The lower substrate dielectric structure 131L may comprise one or more dielectric layers and the lower substrate conductive structure 132L may comprise one or more conductive layers. In particular, the lower substrate dielectric structure 131L may comprise multiple dielectric layers that are alternately stacked or interleaved with one or more conductive layers of the lower substrate conductive structure 132L. In the lower substrate conductive structure 132L, the conductive structures in contact with the alignment interconnects 126a, 126b and the internal interconnects 145 may be referred to as lower substrate upper terminals 132La. In the lower substrate conductive structure 132L, the conductive structures located at the lower side of the lower substrate dielectric structure 131L may be referred to as lower substrate lower terminals 132Lb. The lower substrate 130L may have elements, features, materials, and/or manufacturing methods that are similar to or the same as those of the upper substrate 130U.

Although the completed lower substrate 130L is shown as including a lower substrate dielectric structure 131L comprising two dielectric layers, and a two-layer lower substrate conductive structure 132L, the number of layers constituting the lower substrate dielectric structure 131L and the number of layers constituting the lower substrate conductive structure 132L may be fewer than or more than two.

FIG. 2I shows a cross-sectional view of the electronic device 100 at a later stage of manufacture. In the example shown in FIG. 2I, the lower substrate interconnects 170 may be provided on the lower substrate lower side.

The lower substrate interconnects 170 may be coupled to and in contact with the lower substrate lower terminals 132Lb of the lower substrate conductive structure 132L. In some examples, the lower substrate interconnects 170 may comprise tin (NS), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, the lower substrate interconnects 170 may be provided through a reflow process after forming a conductive material including solder on lower substrate lower terminals 132Lb through a ball drop method. The lower substrate interconnects 170 may comprise or be referred to as conductive balls such as solder balls, conductive pillars such as copper pillars, or conductive posts having solder caps provided on copper pillars. In some examples, the sizes of each lower substrate interconnect 170 may range from approximately 0.5 μm to approximately 1000 μm.

After the lower substrate interconnects 170 are provided, the electronic device 100 may be subjected to a singulation process where the lower encapsulant 140L, the upper encapsulant 140U, the upper substrate 130U, and the lower substrate 130L are sawed along streets S to be separated into individual electronic devices 100. In some examples, the singulation process may be performed by using either a diamond blade or a laser beam. The second carrier 20 attached to the upper side of individual electronic devices 100 may also be removed. In some examples, the lower substrate interconnects 170 may be referred to as external input/output terminals of individual electronic devices 100.

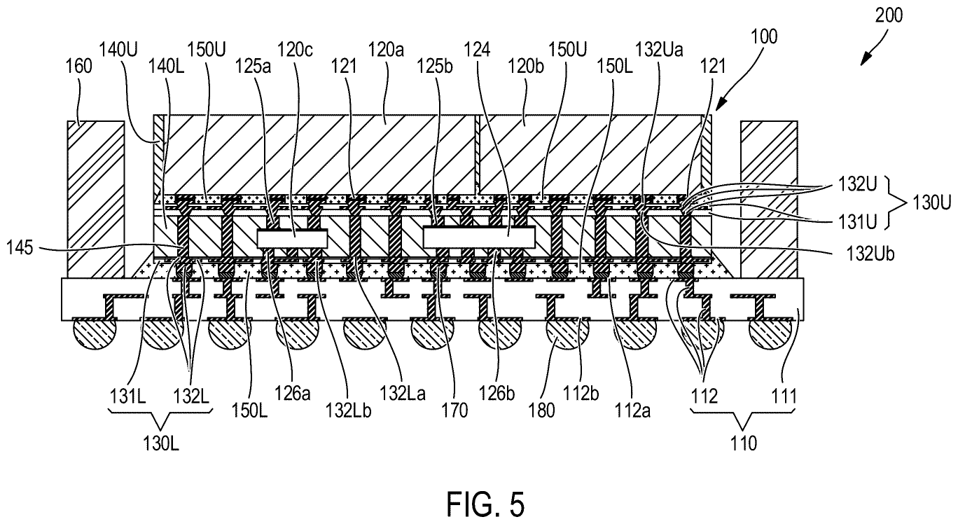

Turning now to FIG. 5, a cross-sectional view of an electronic device 200 is shown. In accordance with various examples, electronic device 200 may include electronic device 100, device substrate 110, lower underfill 150L, and external interconnects 180. In some examples, electronic device 200 may further include a stiffener 160.

The device substrate 110 may comprise a device substrate dielectric structure 111 and a device substrate conductive structure 112. The device substrate conductive structure 112 may comprise device substrate upper terminals 112a and device substrate lower terminals 112b.

Electronic device 100 may be coupled to device substrate 110. For example, lower substrate interconnects 170 may be coupled to and/or contacting device substrate upper terminals 112a.

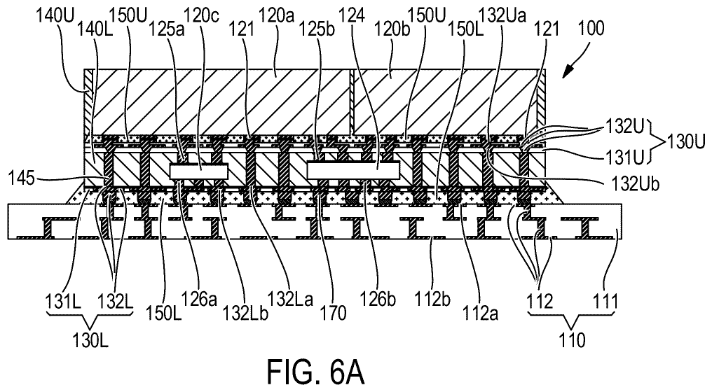

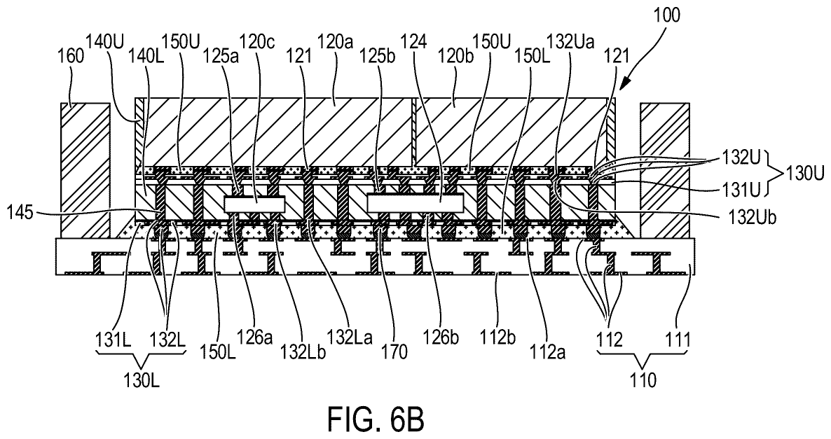

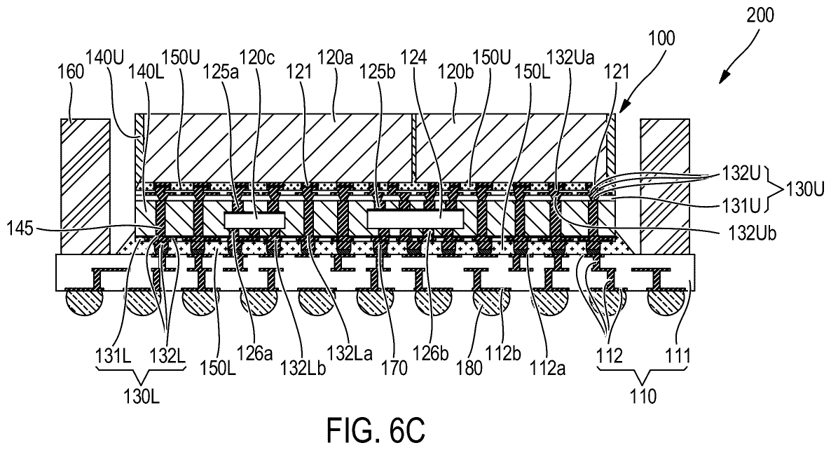

FIGS. 6A to 6C show cross-sectional views of an example method for manufacturing the electronic device 200. FIG. 6A shows a cross-sectional view of the electronic device 200 at a stage of manufacture continuing from FIG. 2I. In the example shown in FIG. 6A, individual electronic devices 100 may be seated on the device substrate 110, and the lower underfill 150L may be provided between the individual electronic devices 100 and the device substrate 110.

The device substrate 110 may comprise a device substrate dielectric structure 111 and a device substrate conductive structure 112. In some examples, the device substrate dielectric structure 111 may comprise or be referred to as one or more stacked dielectric layers. For instance, the one or more dielectric layers may comprise, one or more core layers, polymer layers, pre-preg layers, or solder mask layers stacked on each other. One or more layers or elements of the device substrate conductive structure 112 may be interleaved with one or more layers or elements of the device substrate dielectric structure 111. In some examples, the device substrate dielectric structure 111 may comprise or be referred to as polyimide (PI), benzocyclobutene (BCB), polybenzoxazole (PBO), resin, Ajinomoto Buildup Film (ABF), epoxy or ceramic. In some examples, the thickness of device substrate dielectric structure 111 may range from approximately 10 μm to 1000 μm.

The device substrate conductive structure 112 may comprise one or more conductive layers that define conductive paths with elements such as traces, pads, vias, and wiring patterns. The device substrate conductive structure 112 may comprise device substrate upper terminals 112a provided on an upper side of the device substrate 110, device substrate lower terminals 112b provided on a lower side of the device substrate 110. The lower substrate interconnects 170 of an individual electronic device 100 may be in contact with and be electrically connected to device substrate upper terminals 112a of the device substrate 110.

The device substrate upper terminals 112a may be provided at the device substrate upper side and the device substrate lower terminals 112b may be provided at the device substrate lower side in a respective matrix form having rows and/or columns. In some examples, the device substrate upper terminals 112a and the device substrate lower terminals 112b may comprise or be referred to as a conductor, a conductive material, a substrate land, a conductive land, a substrate pad, a wiring pad, a connection pad, a micro pad, or under-bump-metallurgy (UBM).

The device substrate conductive structure 112 may be provided in the device substrate dielectric structure 111 to couple the device substrate upper terminals 112a with the device substrate lower terminals 112b. In some examples, the device substrate conductive structure 112 may comprise copper, iron, nickel, gold, silver, palladium, or tin.

In some examples, the device substrate 110 may comprise or be referred to as a laminate substrate, a ceramic substrate, a rigid substrate, a glass substrate, a silicon substrate, a printed circuit board, a multilayer substrate, or a molded lead frame. In some examples, the device substrate 110 may comprise or be referred to as an RDL substrate, a buildup substrate, or a coreless substrate. In some examples, the device substrate 110 may have an area varying according to the area or number of electronic components 120 and may have an area of approximately 8 mm×8 mm to approximately 500 mm×500 mm. The device substrate 110 may have a thickness of approximately 0.05 mm to approximately 4 mm.

The device substrate 110 may be electrically connected to the first and second electronic components 120a, 120b through the lower substrate interconnects 170, the lower substrate 130L, the internal interconnects 145, and the upper substrate 130U. The device substrate 110 may be further electrically connected to the first and second electronic components 120a, 120b through the lower substrate interconnects 170, the lower substrate 130L, the connect component 124, and the upper substrate 130U. The device substrate 110 may be further electrically connected to the first electronic component 120a and/or the second electronic component 120b through the lower substrate interconnects 170, the lower substrate 130L, the third electronic component 120c, and the upper substrate 130U.

The lower underfill 150L may be provided between the device substrate upper side the lower side of the electronic device 100. The lower underfill 150L may be in contact with the device substrate upper side, sidewalls of lower substrate interconnects 170, and the lower substrate lower side. In some examples, the lower underfill 150L may help prevent electronic devices 100 from being separated from the device substrate 110 due to physical and/or thermal impacts. The lower underfill 150L may have corresponding elements, features, materials, and/or manufacturing methods similar to those of the upper underfill 150U.

FIG. 6B shows a cross-sectional view of the electronic device 200 at a later stage of manufacture. In the example shown in FIG. 6B, a stiffener 160 may be provided on device substrate 110. The stiffener 160 may be attached to the device substrate upper side and/or may surround the electronic device 100. The stiffener 160 may comprise four square side walls connected to each other. The stiffener 160 may have four square side walls spaced apart from the sidewalls of the electronic device 100. The stiffener 160 may have a square or rectangular ring shape in a plan (top down) view. The lower side of the sidewall of stiffener 160 may be coupled to the upper side of device substrate 110 through an adhesive layer. Stiffener 160 may help reduce or prevent warpage of device substrate 110. In some examples, stiffener 160 may comprise stainless steel, polymer, silicon, metal, glass, or ceramic.

FIG. 6C shows a cross-sectional view of the electronic device 200 at a later stage of manufacture. In the example shown in FIG. 6C, external interconnects 180 may be provided along the lower side of the device substrate 110. The external interconnects 180 may be in contact with and be electrically connected to the device substrate lower terminals 112b. The external interconnects 180 may be ball-grid arrayed or land-grid-arrayed along the device substrate lower side. In some examples, the size of each external interconnect 180 may range from approximately 10 μm to approximately 800 μm. In some examples, the external interconnects 180 may be referred to as external input/output terminals of the electronic device 200. The external interconnects 180 may have elements, features, materials, and/or manufacturing methods similar to or the same as those of lower substrate interconnects 170.

The completed the electronic device 200 may comprise the device substrate 110, first electronic component 120a, second electronic component 120b, third electronic component 120c, connect component 124 (or connect component 124′ or 124″), lower substrate 130L, upper substrate 130U, lower encapsulant 140L, upper encapsulant 140U, internal interconnects 145, stiffener 160, lower substrate interconnects 170, and external interconnects 180. In some examples, the electronic device 200 may comprise lower underfill 150L and upper underfill 150U. In some examples, one or more electronic components 120 may be additionally provided on the device substrate lower side. For example, one or more electronic components 120 may be in contact with and be electrically connected to device substrate lower terminals 112b.

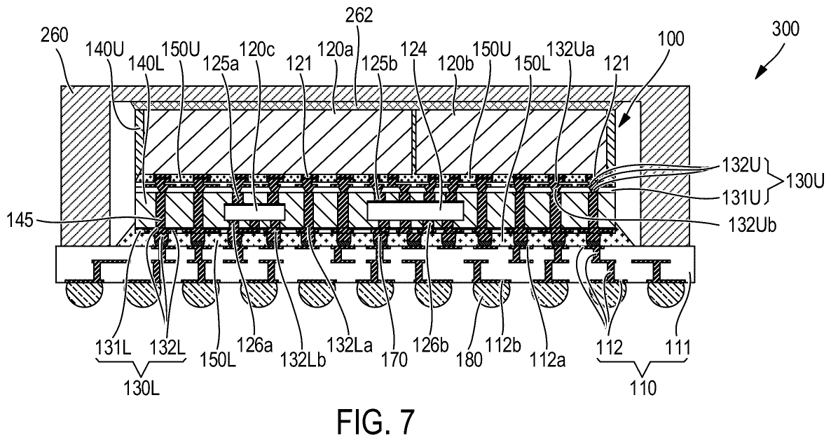

FIG. 7 shows an example electronic device 300. Electronic device 300 may be similar to electronic device 200. For example, electronic device 300 may comprise the device substrate 110, first electronic component 120a, second electronic component 120b, third electronic component 120c, connect component 124 (or connect component 124′ or 124″), lower substrate 130L, upper substrate 130U, lower encapsulant 140L, upper encapsulant 140U, internal interconnects 145, lower substrate interconnects 170, external interconnects 180, lower underfill 150L and upper underfill 150U. In accordance with various examples, device 300 may further include a lid 260 and an attachment material 262.

Lid 260 may be provided on the upper side of the first and second electronic components 120a, 120b exposed to the upper side of the upper encapsulant 140U. Lid 260 may be coupled to the upper side of device substrate 110. In some examples, lid 260 may be electrically coupled to device substrate conductive structure 112. Attachment material 262 may be interposed between the lid 260 and first and electronic components 120a, 120b to facilitate heat transfer and coupling. The attachment material 262 may comprise or be referred to as an adhesive, a thermal interface material (TIM) layer, or solder. In some examples, the attachment material 262 may comprise a back side metal (BSM) located on the upper sides of the first and second electronic components 120a, 120b. The lid 260 may be made of metal with high heat conduction. In some examples, the lid 260 may comprise aluminum or copper. In some examples, the lid 260 may comprise a top plate connected the upper sides of the lid sidewalls. For example, the lid 260 may cover the sidewall and the upper side of the electronic device 100. The top plate of the lid 260 may be attached to the upper sides of first and electronic components 120a, 120b of the electronic device 100 through a TIM layer. In some examples, the lid 260 may be referred to as or comprise a heat sink, a heat dissipation plate, a cap cover, an encapsulation portion, a protective portion, a package, or a body. In some examples, the lid 260 may provide electromagnetic interference (emi) shielding.

In summary, a method of manufacturing an electronic device may include providing alignment conductive pads and internal interconnects along an upper side of a first carrier and coupling alignment interconnects of a connect component to the alignment conductive pads. The method also includes encapsulating the connect component and the internal interconnects in a lower encapsulant, and covering an upper side of the lower encapsulant with an upper substrate. The method also includes coupling, via the upper substrate, first interconnects of a first electronic component and a second electronic component to the connect component interconnects and second interconnects of the first electronic component and the second electronic component to the internal interconnects. The method further includes removing the first carrier from a lower side of the lower encapsulant, and covering the lower side of the lower encapsulant with a lower substrate.

The present disclosure includes reference to certain examples; however, it will be understood by those skilled in the art that various changes may be made, and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. A method of manufacturing an electronic device, the method comprising:
providing alignment conductive pads and internal interconnects along an upper side of a first carrier;
coupling alignment interconnects along a lower side of a connect component to the alignment conductive pads along the upper side of the first carrier;
encapsulating the connect component and the internal interconnects in a lower encapsulant;
covering an upper side of the lower encapsulant with an upper substrate such that an upper substrate conductive structure is coupled to an upper side of each internal interconnect and an upper side of each component interconnect;
coupling, via the upper substrate, first component interconnects of a first electronic component to connect component interconnects along an upper side of the connect component and second component interconnects of the first electronic component to the internal interconnects;
coupling, via the upper substrate, first interconnects of a second electronic component to the connect component interconnects and second interconnects of the second electronic component to the internal interconnects;
removing the first carrier from a lower side of the lower encapsulant; and
covering the lower side of the lower encapsulant with a lower substrate such that a lower substrate conductive structure is coupled to a lower side of each internal interconnect and a lower side of each component interconnect.

2. The method of claim 1, comprises removing a lower portion of each internal interconnect, a lower portion of the lower encapsulant, and a lower portion of each alignment conductive pad.

3. The method of claim 2, comprises completely removing each alignment conductive pad and exposing a lower side of each alignment interconnect.

4. The method of claim 3, comprises removing a lower portion of each alignment interconnect.

5. The method of claim 2, wherein the removing the lower portion of each internal interconnect, the lower portion of the lower encapsulant, and the lower portion of each alignment conductive pad comprises grinding the lower side of each internal interconnect, the lower side of the lower encapsulant, and a lower side of each alignment conductive pad.

6. The method of claim 2, wherein the removing the lower portion of each internal interconnect, the lower portion of the lower encapsulant, and the lower portion of each alignment conductive pad comprises etching the lower side of each internal interconnect, the lower side of the lower encapsulant, and a lower side of each alignment conductive pad.

7. The method of claim 1, comprising providing lower substrate interconnects along the lower side of the lower substrate.

8. The method of claim 7, comprising coupling the lower substrate interconnects to an upper side of a device substrate.

9. The method of claim 8, comprising providing an underfill between the lower side of the lower substrate and the upper side of the device substrate.

10. The method of claim 8, comprising coupling a lid that covers the first electronic component and the second electronic component to the upper side of the device substrate.

11. The method of claim 1, comprising encapsulating the first electronic component and the second electronic component in an upper encapsulant.

12. The method of claim 1, comprising providing an underfill between the upper side of the upper substrate and lower sides of the first electronic component and the second electronic component.

13. The method of claim 12, comprising encapsulating the first electronic component and the second electronic component in an upper encapsulant that encapsulates and contacts the underfill.

14. The method of claim 1, wherein the coupling of the first interconnects of the first electronic component to the connect component via the upper substrate electrical couples the first electronic component to the lower substrate via through interconnects of the connect component.

15. The method of claim 1, wherein the coupling of the first interconnects of the first electronic component and the first interconnects of the second electronic component to the connect component via the upper substrate electrically couples the first electronic component to the second electronic component through a signal distribution structure of the connect component.

16. An electronic device, comprising:
a lower substrate comprising an upper side and a lower side;
an upper substrate comprising an upper side and a lower side;
internal interconnects that couple the upper side of the lower substrate to the lower side of the upper substrate;
a connect component comprising component interconnects along an upper side of the connect component and alignment interconnects along a lower side of the connect component, wherein the component interconnects are coupled to the lower side of the upper substrate, and the alignment interconnects are coupled to the upper side of the upper substrate;
a lower encapsulant that encapsulates the internal interconnects and the connect component;
a first electronic component coupled to the internal interconnects and the connect component via the upper side of the upper substrate;
a second electronic component coupled to the internal interconnects and the connect component via the upper side of the upper substrate; and
lower substrate interconnects along the lower side of the lower substrate.

17. The electronic device of claim 16, wherein the connect component comprises through interconnects that couple the component interconnects to the alignment interconnects.

18. The electronic device of claim 16, wherein the connect component comprises a signal distribution structure that electrically couples the first electronic component to the second electronic component.

19. The electronic device of claim 16, comprising a device substrate coupled to the lower substrate interconnects.

20. The electronic device of claim 19, comprising:
an upper underfill between the upper side of the upper substrate and lower sides of the first electronic component and the second electronic component; and
a lower underfill between the upper side of the device substrate and the lower side of the lower substrate.
